(19) United States
(12) Patent Application Publication
(10) Pub. No.: US 2002/0074566 A1
(43) Pub. Date: Jun. 20, 2002

(54) Bonding pad structure to avoid probing damage

(76) Inventors: Ming-Dou Ker, Hsinchu (TW); Chyh-Yih Chang, Hsinchuang (TW); Hsin-Chin Jiang, Taipei (TW)

Correspondence Address: RABIN & CHAMPAGNE, PC, 1101 14TH STREET, NW, SUITE 500, WASHINGTON, DC, 20005, US

(21) Appl. No.: 09/935,796

(22) Filed: Aug. 24, 2001

(30) Foreign Application Priority Data
Dec. 15, 2000 (TW) 089126820

(51) Int. Cl. H01L 31/0328; H01L 31/0336; H01L 31/072; H01L 31/109

(52) U.S. Cl. 257/200

(57) ABSTRACT

A bonding pad structure to avoid probing damage applied to IC or PCB products comprises a first pad and at least one second pad. The first pad is coupled with the second pad. The first pad is used for wire bonding & packaging while the second pad is used for probing in IC function testing. Therefore, it avoids the probing damage of the first pad after the IC function testing and further increases the IC reliability while wire bonding & packaging.

This application incorporates by reference Taiwanese application Serial No. 089126820, Filed Dec. 15, 2000.

### BACKGROUND OF THE INVENTION

1. Field of the Invention

The invention relates in general to a bonding pad structure for the Integrated Circuit (IC) or Printed Circuit Board (PCB), and more particularly to a bonding pad structure to avoid probing damage.

2. Description of the Related Art

A conventional basic procedure of manufacturing an Integrated Circuit (IC) product is shown in FIG. 1. The IC design layout 101 is first started and the semiconductor process 102 is then performed. The traditional semiconductor process in the semiconductor foundry includes the steps of etching & CMP (Chemical-Mechanical Polishing), ion implantation, thin film process and lithography. After finished the step of the semiconductor process 102, the step of the IC function and reliability testing 103 is performed. The tested dies are moved to the chip package plant for the step of processing wire bonding & packaging 104. The IC products 106 are produced after processed the step of IC final testing 105.

The bonding pad for IC is the communication channel for IC signal. Basically, the bonding pad is composed by several metal films, which are connected by vias of each layer. A good bonding pad requires excellent adhesion to the bonding wire, the endurance about high electric currents for a long operating time and good reliability.

The bonding pad is of great significance to IC. Several companies compete in related patents about the bonding pad. The U.S. Pat. No. 6,060,378 “Semiconductor bonding pad for better reliability” of Micron Technology discloses a multi-layer manufacturing process to improve reliability of bonding pad.

Moreover, the U.S. Pat. No. 5,891,745 “Test and tear-away bond pad design” of Honeywell Inc. discloses a process of providing a bond pad arrangement, which allows the wire to be removed and does not affect the production assembly bond pad.

Furthermore, the U.S. Pat. No. 5,565,385 “Semiconductor bond pad structure and increased bond pad count per die” of LSI Logic Corporation discloses a non-square bond pad to increase bond pad density and minimize lift-off problems.

While the step of the IC function and reliability testing 103 is performing, the probes need to be inserted to connect the bonding pad for testing the IC. As shown in FIG. 2, however, it used to cause probing damage and make the bonding pad rough and uneven in surface after probing (as indicated by arrow 301). Sometimes, the probes may punch holes in the metal surface layer of the bonding pad. The damaged bonding pad is harmful for the step of the wire bonding & packaging 104 and decreases the yield rate of IC products.

### SUMMARY OF THE INVENTION

It is therefore an object of the invention to provide a bonding pad structure to avoid probing damage for increasing the yield rate of the IC or PCB products.

The invention achieves the above-identified objects by providing a bonding pad structure applied to IC or PCB products. The bonding pad structure comprises a first pad and at least one second pad. The first pad is used for bonding while the second pad coupled with the first pad is used for probing.

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 (Prior Art) illustrates a conventional basic procedure of manufacturing an IC product;

FIG. 2 (Prior Art) shows the bonding pad damage by the testing probes;

FIG. 3A shows a schematic view of a bonding pad structure according to a preferred embodiment of the invention;

FIG. 3B shows a cross-sectional view of a bonding pad structure according to a preferred embodiment of the invention;

FIG. 4A shows a linear pad layout style of bonding pads according to a preferred embodiment of the invention;

FIG. 4B shows a staggered pad layout style of bonding pads according to a preferred embodiment of the invention;

FIG. 4C shows another pad layout style of bonding pads according to another preferred embodiment of the invention;

FIG. 5 shows a bonding pad structure applied to a high-pin-count IC according to a preferred embodiment of the invention;

FIG. 6A shows a top view of a bonding pad structure applied to flip chip in IC function testing according to a preferred embodiment of the invention; and

FIG. 6B shows a cross-sectional view of a bonding pad structure applied to flip chip according to a preferred embodiment of the invention.

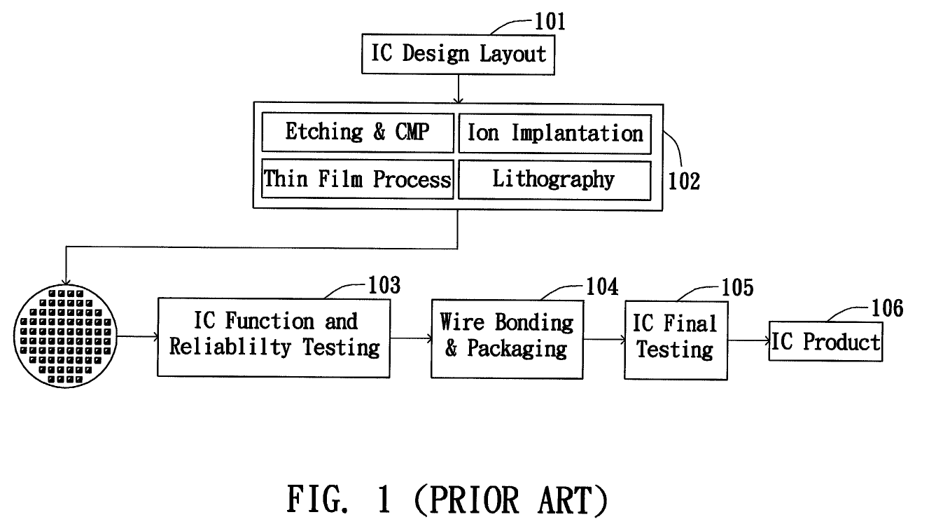

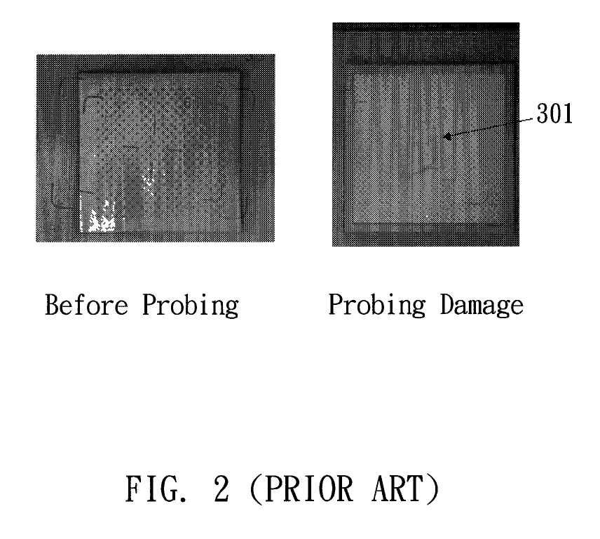

### DESCRIPTION OF THE PREFERRED EMBODIMENT

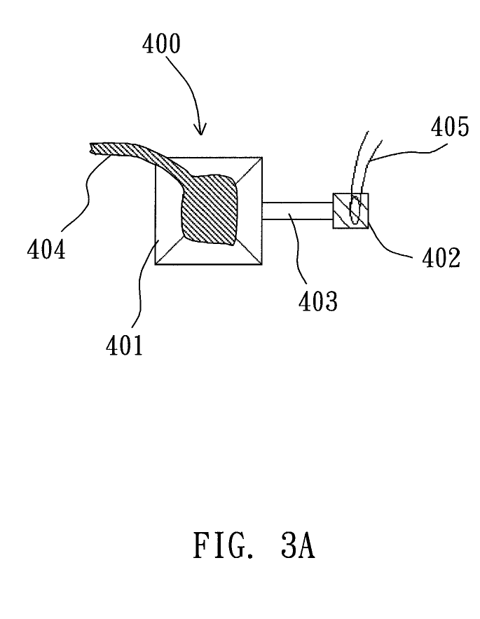

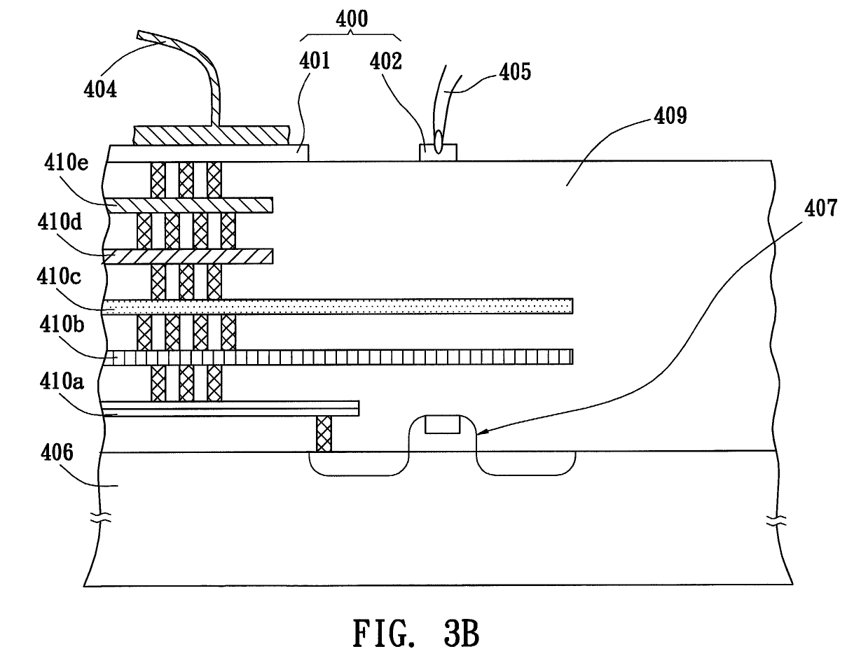

Referring to FIG. 3A, a schematic view of a bonding pad structure according to a preferred embodiment of the invention is shown. The bonding pad 400 comprises a first pad 401 and a second pad 402. The first pad 401 requires to be coupled with the second pad 402 preferably by a connecting wire 403. The first pad 401, second pad 402 and the connecting wire 403 can be made in the same manufacturing step to simplify the manufacturing process. It will not increase any mask or manufacturing step. The first pad 401 is used for wire bonding & packaging 104, and the second pad 402 is for probing therein. As shown in FIG. 3A, the first pad 401 has a bonding wire 404 on it. The second pad 402 is contacted by a testing probe 405 and the testing probe 405 is used in IC function testing. Since the first pad 401 is separated from the second pad 402, it does not affect the wire bonding & packaging function of the first pad 401 even if the testing probe 405 damages the second pad 402. This invention can also applied to the bonding pad structure for PCB.

Referring to FIG. 3B, a cross-sectional view of a bonding pad structure according to a preferred embodiment of the invention is shown. A typical IC includes a substrate 406, an active component 407, a inter-linkage wire of multi-metal layer which is composed of metal layer 410a, 410b, 410c, 400d and 410e, and a dielectric layer 409. The bonding pad 400 of the invention, as shown in FIG. 3B, there is a thick dielectric layer 409 located between the second pad 402 and active component 407. Therefore, even if the second pad 402 is damaged when probing to IC, the active component 407 will not be damaged.

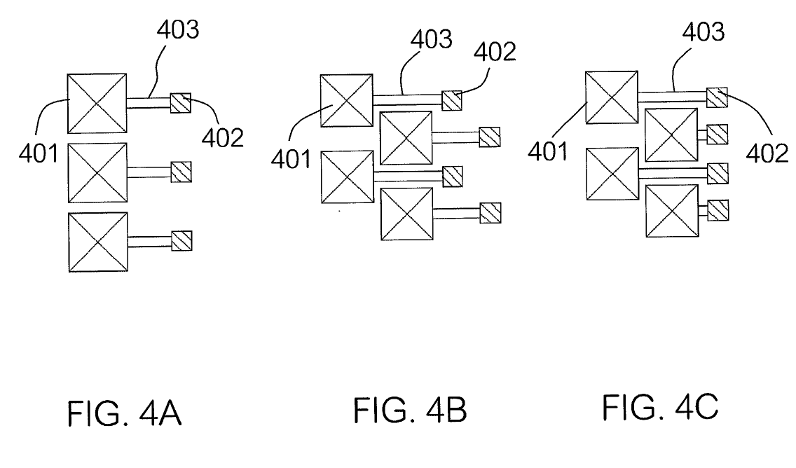

FIG. 3A and FIG. 3B show the structural diagrams of a singular bonding pad structure while FIG. 4A, FIG. 4B and FIG. 4C show the application and arrangement of plural bonding pads. The arrangement of plural bonding pads is not limited within the embodiments but depends on the testing probes in IC function testing. The linear pad layout style of bonding pads according to a preferred embodiment of the invention is shown in FIG. 4A. The staggered pad layout style of bonding pads according to a preferred embodiment of the invention is shown in FIG. 4B. Another pad layout style of bonding pads according to another preferred embodiment of the invention is shown in FIG. 4C. The first pad 401 layout is arranged in staggered and the second pad 402 layout is arranged in linear.

As the age of the system chip is coming, the chip equips diverse functions that the demand of the number of I/O pad increases rapidly. The high-pin-count IC has become the main trend in the future. The bonding pad structure according to the preferred embodiment of the invention is especially suitable for applied in the high-pin-count IC.

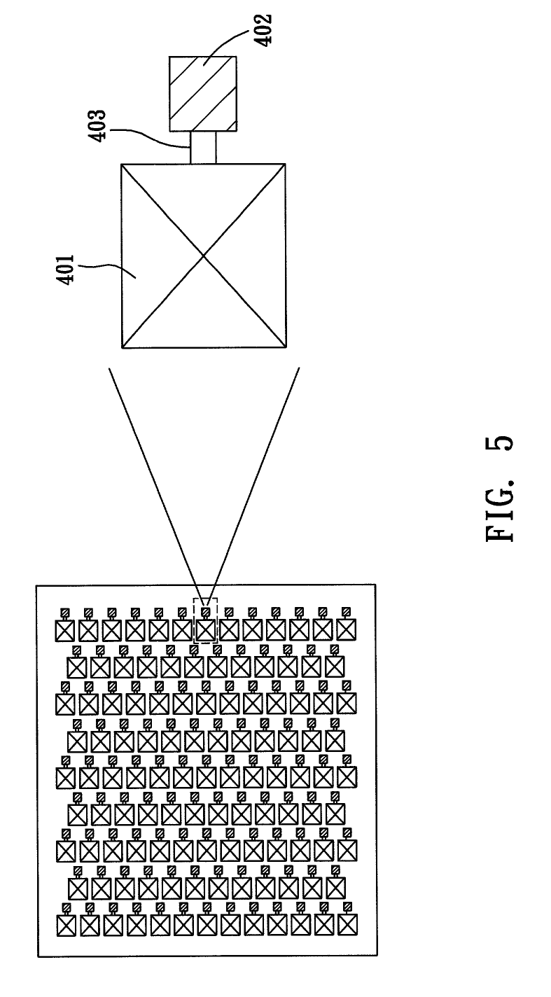

Referring to FIG. 5, a bonding pad structure applied to a high-pin-count IC according to a preferred embodiment of the invention is shown, especially an application to flip chip. The high-pin-count IC can not be completely packaged if there is any bonding pad damaged. Therefore, applying the bonding pad structure of the invention to the high-pin-count IC can increase the yield rate and decrease the cost. As shown in FIG. 5, each first pad 401 is coupled with a corresponding second pad 402 preferably by a connecting wire 403.

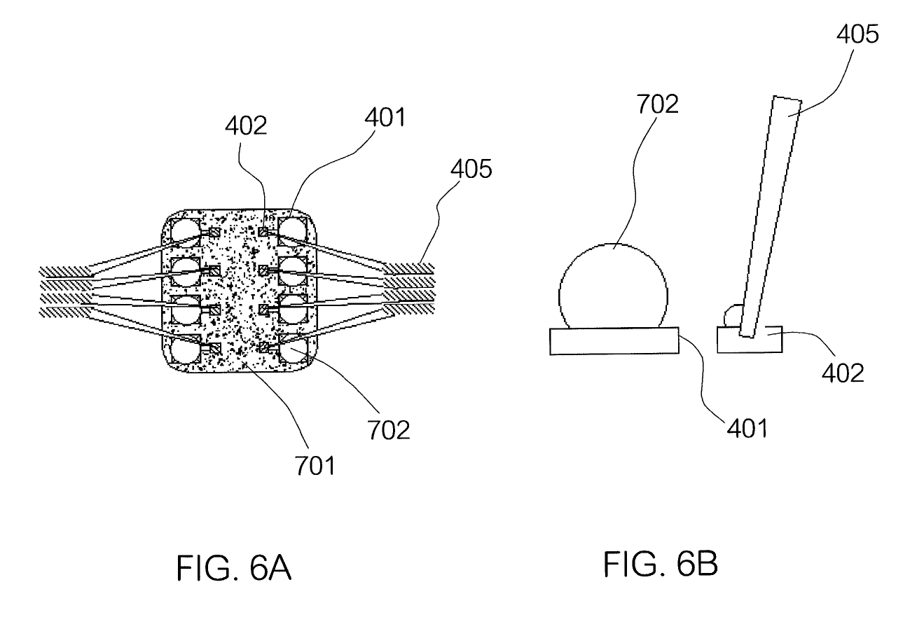

Referring to FIG. 6A, a top view of a bonding pad structure applied to flip chip according to a preferred embodiment of the invention is shown. Only part of the chip 701 is shown for clearness. Referring also to FIG. 6B, a cross-sectional view of a bonding pad structure 400 applied to flip chip according to a preferred embodiment of the invention is shown.

In case that the bonding pad structure applied to flip chip, the bump ball 702 only needs to grow on the first pad 401 for wire bonding & packaging but not on the second pad 402. The testing probe 405 can just probe to the second pad 402 to perform testing without touching the bump ball 702 on the first pad 401 and the bump ball 702 would not be damaged. Referring to FIG. 6B, the bump ball 702 is not damaged though the testing probe 405 does damage the surface of the second pad 402 in testing process. Therefore, it ensures the perfect surface of the bump ball 702 in the next process of flip chip bonding and packaging. Besides, the reliability of the bonding pad is controllable. As for some specific IC products, there are several different probing or testing that each first pad can be coupled with more than one second pad.

The bonding pad structure according to the invention has the following advantages:

First, it avoids the damage of the first pad of the bonding pad when the test probe probing.

Second, it further increases the controllability while flip chip bonding and packaging.

Third, it avoids decreasing the endurance about high electric currents for a long operating time and the good reliability due to the probing damage of the bonding pad.

Fourth, it can easily solve the probing damage of the bonding pad without increasing the complexity of the IC manufacturing and packaging process.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A bonding pad structure comprising:
a first pad; and
at least one second pad coupled with the first pad.

2. The bonding pad structure according to claim 1, wherein the first pad is coupled with the second pad by a connecting wire.

3. The bonding pad structure according to claim 1, wherein the arrangement of the corresponding second pad depends on the arrangement of testing probe in IC probing.

4. The bonding pad structure according to claim 3, wherein the first pad layout and the second pad layout are arranged in linear.

5. The bonding pad structure according to claim 3, wherein the first pad layout and the second pad layout are arranged in staggered.

6. The bonding pad structure according to claim 3, wherein the first pad layout is arranged in staggered and the second pad layout is arranged in linear.

7. The bonding pad structure according to claim 1, wherein the first pad comprises a bump ball.

8. The bonding pad structure according to claim 1 applied to a flip chip.
